(19) United States
(12) Patent Application Publication
(10) Pub. No.: US 2019/0115293 A1
(43) Pub. Date: Apr. 18, 2019

(54) MULTIPLE BALL GRID ARRAY (BGA) CONFIGURATIONS FOR A SINGLE INTEGRATED CIRCUIT (IC) PACKAGE

(71) Applicant: Intel Corporation, Santa Clara, CA (US)

(72) Inventors: MD Altaf Hossain, Portland, OR (US); Ankireddy Nalamalpu, Portland, OR (US); Dheeraj Subbareddy, Portland, OR (US); Dinesh Somasekhar, Portland, OR (US)

(21) Appl. No.: 16/218,331

(22) Filed: Dec. 12, 2018

(51) Int. Cl. H01L 23/498; H01L 23/00; H03K 19/177; H05K 1/18; H01L 27/02

(52) U.S. Cl. CPC H01L 23/49816; H01L 24/09; H01L 24/17; H05K 2201/10159; H05K 1/181; H01L 27/0207; H01L 2924/15311; H03K 19/1776

(57) ABSTRACT

An integrated circuit package may include a semiconductor die on a first side of the integrated circuit package, a first ball grid array (BGA) connection on the first side of the integrated circuit package, and a second BGA connection on a second side of the integrated circuit package. The integrated circuit package may include one or more traces that route data from the first BGA connection and the second BGA connection.

### BACKGROUND

This disclosure relates to an integrated circuit packaging suitable to support multiple product types. More particularly, the disclosure relates to a packaging configuration to support integrated circuit die communication with memory devices that are either on-package or off-package or both on-package and off-package.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Integrated circuit devices are used in numerous electronic systems. Computers, handheld devices, portable phones, televisions, industrial control systems, robotics, and telecommunication networking—to name just a few—all use integrated circuit devices. Integrated circuit devices may be formed using lithography techniques that pattern circuitry onto a substrate wafer that is diced to form a number of (generally identical) individual integrated circuit dies. Each integrated circuit die may include many different components, such as programmable logic fabric, digital or analog signal transmission circuitry, digital signal processing circuitry, application-specific data processing circuitry, memory, and so forth. Multiple integrated circuit dies and components may be packaged on a substrate, forming an integrated circuit package. The package may include electrical connections that connect the die and other components to the printed circuit board (PCB) and pins or leads that may be utilized for the electrical connections to circuits, power, and ground external to the integrated circuit. Thus, the package may serve as the interface between the dies and the PCB.

In general, components included in an integrated circuit and package may be based on different underlying technologies. That is, a different package may be used for various sets of technological specifications, resulting in a range of package sizes and configurations. As a result, the variety of package specifications for different technologies may result in producing a different tape-out for each of the various package specifications. These different tape-out solutions may increase costs and involve more time to design and manufacture.

### BRIEF DESCRIPTION OF THE DRAWINGS

Various aspects of this disclosure may be better understood upon reading the following detailed description and upon reference to the drawings in which:

FIG. 1 is a block diagram of a programmable logic device that is programmed with a circuit design, in accordance with an embodiment;

FIG. 2 is a block diagram of a package including the programmable logic device where a fabric die is vertically stacked with a base die, in accordance with an embodiment;

FIG. 3 is a block diagram of a circuit card assembly (CCA) illustrating the programmable logic device of FIG. 2 and memory devices mounted on a printed circuit board (PCB) of the CCA using different packages, in accordance with an embodiment;

FIG. 4 is a block diagram of the circuit card assembly (CCA) of FIG. 3 illustrating the programmable logic device and the memory devices on the same package, in accordance with an embodiment; and

FIG. 5 is a block diagram side view of the package having the programmable logic device and memory devices of FIG. 4, in accordance with an embodiment.

### DETAILED DESCRIPTION OF SPECIFIC EMBODIMENTS

One or more specific embodiments will be described below. In an effort to provide a concise description of these embodiments, not all features of an actual implementation are described in the specification. It may be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it may be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Device performance demands continue to increase as device space dimensions become more constrained. For example, a wireless device operating in high speed networks, is driving packaging solutions to use a variety of compact architectures. In general, an integrated circuit device may be represented as a system of separate integrated circuit dies that may communicate signals between each other in an efficient matter. For instance, in a packaging solution that has two or more dies, the number of connections available between the dies may depend on the amount of available space to route circuitry between different locations of a single monolithic integrated circuit. To conserve space on the integrated circuit, multiple integrated circuit dies may be stacked vertically using various interconnects, as discussed herein, to facilitate communication between the dies.

In some embodiments, the integrated circuit dies may communicate with other components that are disposed on the same package as the respective integrated circuit dies or with components that are disposed on a PCB or other circuit device that is not on the same package of the respective integrated circuit dies (e.g., off-package). By way of example, one or more integrated circuit dies on a package may communicate with memory devices, such as memory chips, that are disposed off of the package. The memory chips may be categorized based on their types and applications. For example, double data rate synchronous dynamic random access memory (DDR SDRAM) offer higher data transfer rates by a strict control of timing of electrical data and clock signals, thereby achieving nearly twice the bandwidth of a single data rate (SDR) SDRAM at the same clock frequency. Similarly, graphics double data rate (GDDR) SDRAM is a type of memory tailored for use with video cards. Both DDR and GDDR memory may be off-package and may use a long trace path between the dies disposed on the package and the memory components disposed off of the package. Furthermore, additional memory devices that the integrated circuit dies may communicate with include, but are not limited to, static random access memory (SRAM) and embedded dynamic random access memory (EDRAM). In contrast to a dynamic random access memory (DRAM), SRAM is a static form of RAM that is not constantly refreshed. SRAM is typically used for secondary device operations, such as cache memory and storing registers. EDRAM is a DRAM that is integrated on the same die or multi-chip module (MCM) of the integrated circuit. Moreover, these memory devices that may be off of the package may consume space on the PCB that may be otherwise used for additional or other circuit components.

Integrated circuit dies or multi-chip systems may also communicate with memory component that are disposed on the same package, such as by a package-on-package (PoP) architecture, which is often used in wireless device applications. Package-on-package architecture includes vertically stacking two or more packages on top of one another, such that signals may be vertically routed between the packages. In any case, integrated circuit dies that communicate with memory components either on-package or off-package each use individual tape-outs and each tape-out has its own respective photomask costs.

It may be desirable to maintain an integrated circuit package architecture that supports communication between components (e.g., one or more dies) on a package and other devices (e.g., memory devices) that are both on the same package and are disposed off of the package. A tape-out is the final result of the design process for integrated circuits or printed circuit boards (PCB) before they are sent for manufacturing. Specifically, the tape-out is the point at which the graphic design for the photomask of the circuit is sent to a fabrication facility. Lithographic photomasks are layer patterns used to create an integrated circuit. As discussed above, different types of integrated circuit applications may include the dies on a package communicating with memory devices on or off of the package that the dies are disposed on. These different types of integrated circuit applications may use a separate tape-out for each package architecture, and thus, use a separate photomask with separate respective costs. Furthermore, each tape-out has respective test interface unit (TIU) testing lead times and corresponding tests costs. Given these various package architectures, one designed package may be incompatible for communication between the dies and memory devices that are on the same package or are off of the package.

To enable efficient use of integrated circuit packages, packages may include ball grid array (BGA) connections that may communicate with memory devices disposed on a package or off of the package via circuit connection on the PCB. For example, in one embodiment, BGA pads on top of the package may enable an integrated circuit die to communicate with one or more memory devices also disposed on the package via the BGA pads. Furthermore, the integrated circuit die may also maintain its ability to communicate with the memory devices off-package via circuit connections disposed on the PCB. Thus, a package that includes BGA pads in conjunction with BGA balls on either side of the package may allow for one or more dies on-package to communicate with components both on and off of the package. As a result, photomask and production costs may be controlled by manufacturing a single package architecture that may facilitate communication with memory devices both on and off-package rather than manufacturing multiple separate package designs.

Furthermore, many of the electronic systems previously mentioned, such as the portable phone or another wireless device, may include integrated circuit dies that communicate with various other devices. For example, various field programmable gate array (FPGA) devices may include an FPGA die that can communicate with other components on-package (e.g., same package as the FPGA die) or off-package (e.g., an off-chip memory device on the PCB) by routing signals between them, such as by conductive traces. As discussed above, the additional components may utilize additional space on the PCB, but reserving PCB space may be especially beneficial for complex devices, such as wireless devices operating in a 5G standard network that may need additional memory devices and components to be placed on the PCB when compared to less bandwidth demanding wireless applications (e.g., 3G or 4G standard).

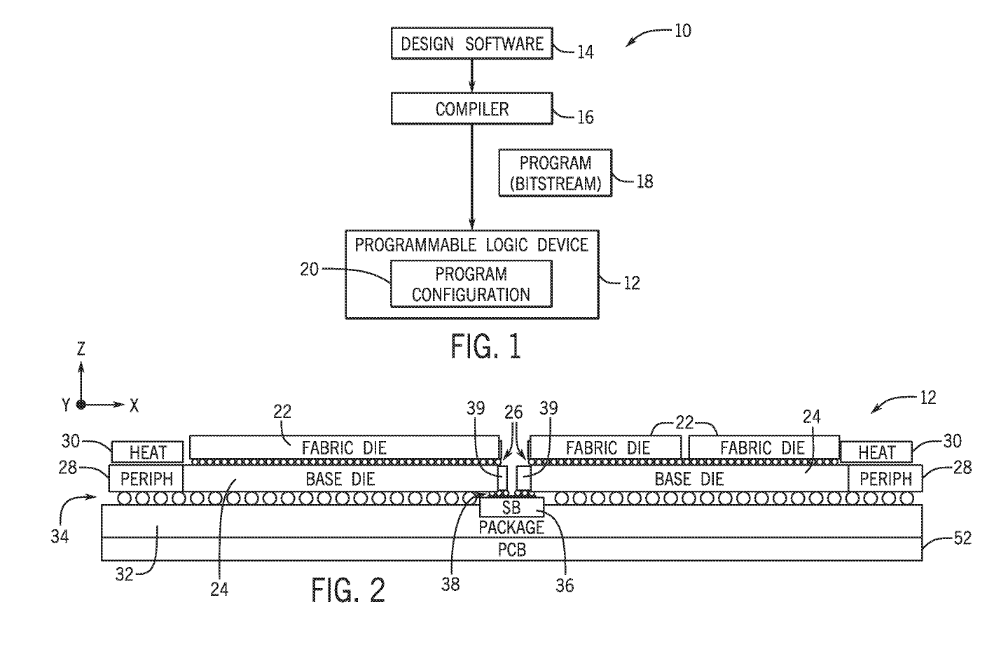

With the foregoing in mind, FIG. 1 illustrates a block diagram of a system 10 that may employ a programmable logic device 12 with one or more dies that may communicate with devices on the same package or on different packages (e.g., elsewhere on the PCB). Using the system 10, a designer may implement a circuit design functionality on an integrated circuit, such as a reconfigurable programmable logic device 12, such as a field programmable gate array (FPGA). The designer may implement a circuit design to be programmed onto the programmable logic device 12 using design software 14, such as a version of Intel® Quartus® by Intel Corporation of Santa Clara, Calif. The design software 14 may use a compiler 16 to generate a low-level circuit-design defined by bitstream 18, sometimes known as a program object file and/or configuration program that programs the programmable logic device 12. Thus, the compiler 16 may provide machine-readable instructions representative of the circuit design to the programmable logic device 12. For example, the programmable logic device 12 may receive one or more configuration programs (bitstreams) 18 that describe the hardware implementations that should be stored in the programmable logic device 12. A configuration program (e.g., bitstream) 18 may be programmed into the programmable logic device 12 as a program configuration 20. The program configuration 20 may, in some cases, represent an accelerator function to perform specialized task, such as video processing, voice recognition, image recognition, vehicle-to-vehicle communication, or other highly specialized task. These specialized task may be used in wireless applications, such as for wireless devices operating in a 5G network.

To carry out application tasks using the package architecture of this disclosure, the programmable logic device 12 may include a fabric die that communicates with a base die. The base die may perform application specific tasks while the fabric die may be used for general purposes. For example, the fabric die may be configured with an accelerator function topology that coordinates with application specific circuitry in the base die. As such, and in one embodiment, the programmable logic device 12 may be the fabric die stacked on the base die, creating a 3D stack to perform application specific tasks, such as for wireless application tasks. In another example, the fabric die may be an FPGA and the base die may be a high-speed transceiver used for wireless applications. In some applications, the base die and the fabric die may be side-by-side and connected to one another via an interposer or bridge (e.g., an embedded multi-die interconnect bridge (EMIB)) in a 2.5D form. As previously discussed, the multiple ball grid array (BGA) connections (e.g., BGA balls on the bottom side of the package and BGA pad on the topside of the package) may allow the base die to communicate with memory devices on-package and off-package. While the examples provided below may refer to the base die communicating with memory devices or components on-package and/or off-package, other types of devices or components communicating with the base die on the integrated circuit package may benefit from this disclosure. These components may include on board power measurement circuitry (e.g., voltage regulator, oscillator, and the like).

One example of the programmable logic device 12 is shown in FIG. 2, but any suitable programmable logic device may be used. In the example of FIG. 2, the programmable logic device 12 includes the fabric die 22 and the base die 24 that are connected to one another via microbumps 26. Although the fabric die 22 and base die 24 appear in a one-to-one relationship in FIG. 2, other relationships may be used. For example, a single base die 24 may attach to several fabric die 22, or several base die 24 may attach to a single fabric die 22, or several base die 24 may attach to several fabric die 22 (e.g., in an interleaved pattern along the x- and/or y-direction). Peripheral circuitry 28 may be attached to, embedded within, and/or disposed on top of the base die 24, and heat spreaders 30 may be used to reduce an accumulation of heat on the programmable logic device 12. The heat spreaders 30 may appear above, as pictured, and/or below the package (e.g., as a double-sided heat sink). The base die 24 may attach to a package 32 substrate via C4 bumps or BGA solder balls 34.

As previously discussed, the package includes the electrical connections (e.g., pins) to support communication between the components (e.g., base die 24) and the PCB. In the example shown in FIG. 2, two pairs of fabric die 22 and base die 24 are shown communicatively connected to one another via a silicon bridge 36 (e.g., an embedded multi-die interconnect bridge (EMIB)) and microbumps 38 at a silicon bridge interface 39. The silicon bridge 36 also represents an interposer that uses the BGA of solder balls 34, which may electrically connect to other circuitry, such as the PCB 52.

Although the microbumps 26 and the microbumps 38 are described as being employed between the fabric die 22 and the base die 24 or between edge devices, such as the silicon bridge 36 and the silicon bridge interface 39, it should be noted that microbumps may be employed at any suitable position between the components of the programmable logic device 12. For example, the microbumps may be incorporated in any suitable position (e.g., middle, edge, diagonal) between the fabric die 22 and the base die 24. In the same manner, the microbumps may be incorporated in any suitable pattern or amorphous shape to facilitate interconnectivity between various components described herein.

It should be understood that FIG. 2 illustrates a 3D arrangement, representing a particular embodiment, in which the fabric die 22 is stacked on top of the base die 24 and the interconnect points or microbumps 26 may directly connect to corresponding interconnect structures on the base die 24. In another embodiment, the fabric die 22 and the base die 24 may be connected in a 2.5D arrangement that uses a silicon bridge 36 to connect the fabric die 22 and the base die 24.

As previously mentioned, one or more dies of the integrated circuit package, such as base die 24, may communicate with memory devices on the package 32 or off of the package 32, on a different package on the PCB 52. In order for a package design used for an integrated circuit that communicates with memory on the package 32 to be used for a different integrated circuit that communicates with memory devices off of the package 32, a new tape-out and photomask with the corresponding package architecture is created. However, by adding BGA connections on both the top side of a package and the bottom side of the package, this multi-functional package architecture that may be utilized by a variety of integrated circuit device design types. The multiple BGA connections may include BGA solder balls 34 on the bottom side of the package (e.g., land side) connecting to the PCB and BGA pads on the top side of the package (e.g., die side) connecting to device components (e.g., one or more dies, memory devices, etc.) Moreover, this multi-functional package architecture may be used for both integrated circuit dies communicating with memory devices on and off of the package. Furthermore, a single tape-out and photomask may be produced for the multi-functional package.

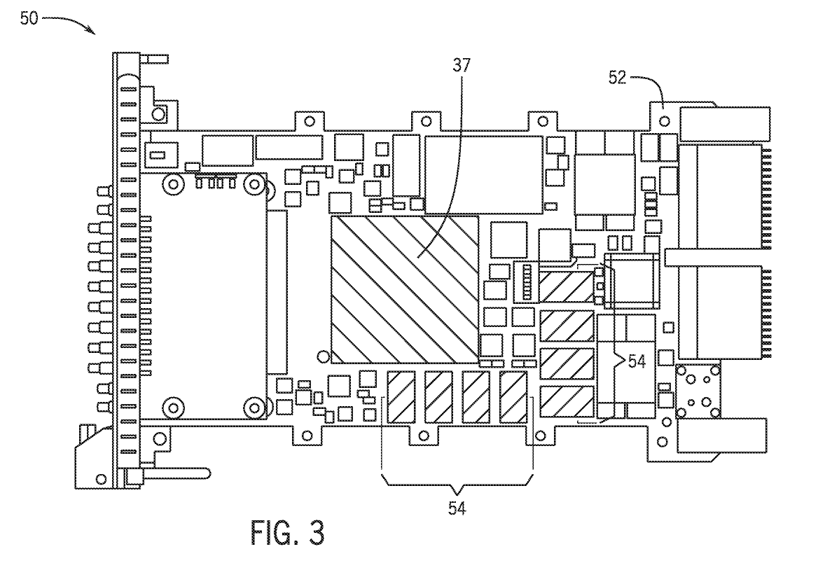

To help illustrate, FIG. 3 depicts a block diagram of a circuit card assembly (CCA) 50 that includes an integrated circuit device and memory devices, among other components. Briefly, the CCA 50 may include an assembled PCB 52 with components. As shown, the CCA 50 includes an integrated circuit device 37 (e.g., programmable logic device 12 of FIGS. 1 and 2) and one or more memory devices 54 mounted on the PCB 52. The integrated circuit device 37 is mounted on the PCB 52 using a package 32 (not shown) while the one or more memory devices 54 are mounted on the PCB 52 separate from the package that stores the integrated circuit device 37. The package that supports the integrated circuit device 37 has its own photomask and tape-out. However, if the integrated circuit device 37 was to communicate with memory devices 54 integrated on the same package in which it is disposed, a different photomask and tape-out for the package would be used to enable the respective communications.

Furthermore, the integrated circuit device 37 used to accelerate application specific tasks may use the off-package memory devices 54 to access stored data for executing such tasks. Since the memory devices 54 are off of the package, bandwidth and/or latency constraints may occur when transferring data to and from the off-package memory devices 54. These latency and package architecture constraints may be mitigated by modifying the package 32, such as by adding additional BGA connections on the other side (e.g., side without BGA solder balls 34) of the existing package 32, to allow the memory devices 54 to communicate with the integrated circuit device 37 on the same package 32 while still allowing communication with additional memory devices 54 off of the package 32.

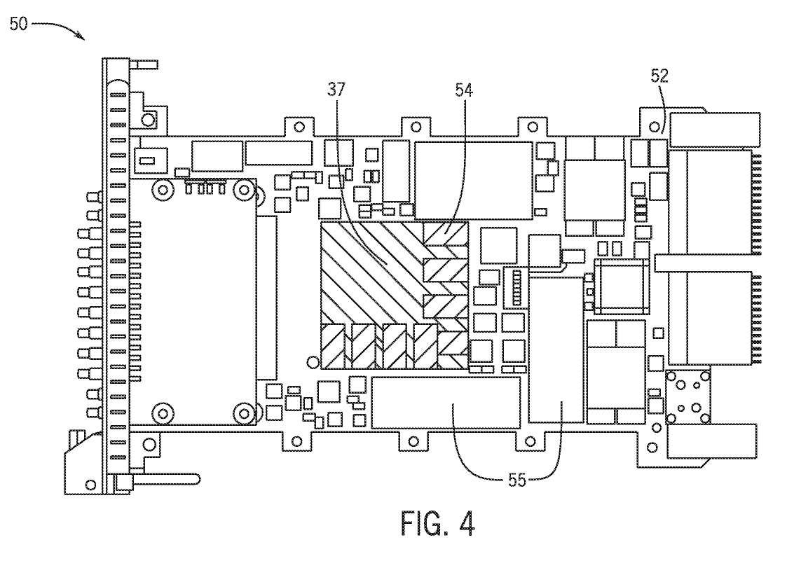

To illustrate, FIG. 4 depicts the integrated circuit device 37 and the memory devices 54 of FIG. 3 on the same package 32 using BGA connections on both the top side and bottom side of the package 32. In this manner, the memory devices 54 that were previously mounted on the PCB 52, but not on the package 32 used for the integrated circuit device 37, can utilize the same package 32, thereby creating additional PCB area 55 that maybe reserved for other devices or components.

Furthermore, since both the integrated circuit device 37 and the memory devices 54 are on the same package 32, data transmissions between the memory devices and the integrated circuit device 37 may avoid using PCB 52 traces. Rather, the additional BGA connections allows the integrated circuit device 37 to communicate with the memory devices 54 through traces of the BGA, allowing for faster data exchange between the devices.

Although some of the following descriptions describe the package 32 modified with BGA solder balls 34 on the bottom side of the package 32 and the BGA pads 35 on the top side of the package 32, which represent a particular embodiment, it should be noted that the modified package architecture described herein may use BGA solder balls 34 on one or more sides of the package, BGA pads 35 on one or more sides of the package 32, such that the single package 32 design may allow the integrated circuit device 37 to communicate with components or devices, such as the memory devices 54, both on the package 32 and off of the package 32.

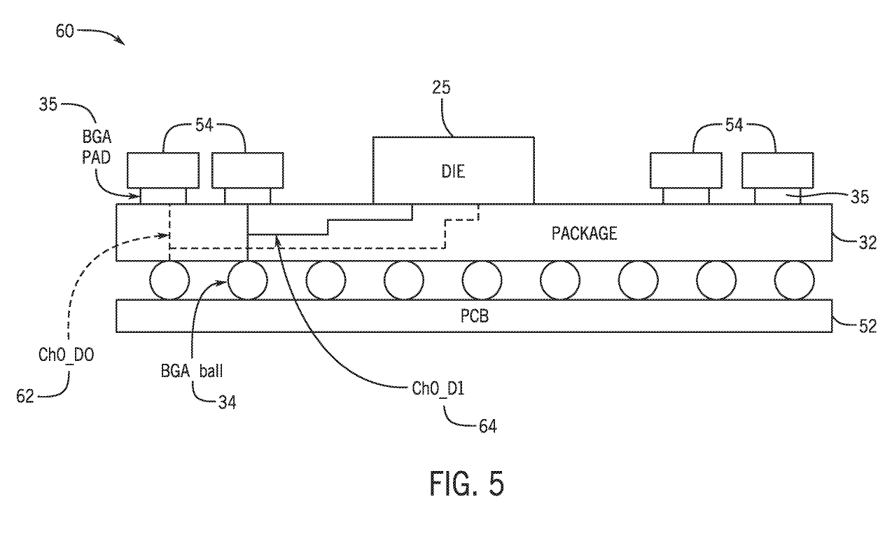

To detail the BGA connections on both the top side of the package 32 that may be connected to one or more dies of the integrated circuit device 37 and the bottom side of the package 32 that may be connected to the PCB 52, FIG. 5 depicts a block diagram 60 of the package 32 with BGA solder balls 34 on the bottom side of the package and BGA pads 35 on the top side of the package. The BGA pads may reference a solder or non-solder surface mount pad (e.g., solder mask defined pad (SMD) or non-solder mask defined pad (NSMD). As shown, the package 32 integrates the BGA pads 35 and BGA solder balls 34 into a single modified multi-functional package 32 design, allowing communication between devices that are connected to either the BGA pads 35 on the top side of the package 32 and/or solder balls 34 on the bottom side of the package 32.

In this example, the memory devices 54 are connected to the BGA pads 35 on the top side of the package 32 along with an integrated circuit die 25 (e.g., a semiconductor die). As previously mentioned, the modified package 32 allows communication between all devices connected to the various BGA connections of the package 32. Channels and/or paths may be routed between the BGA areas to allow for signal communication between the various devices connected to the package 32. Briefly, the channels are used for running traces that are used to communicate signals between devices.

As shown, a first channel 62 (Ch0_D0), which may channel 1, pin D0 of the package 32, may be used for traces between the BGA solder balls 34 to the BGA pads 35, BGA solder balls 34 to the die 25, and the BGA pad 35 to the die 25, thereby allowing traces to run through each of the devices connected to the various sides of the package 32 via the first channel 62. Similarly, a second channel 64, (Ch0_D1), which may reference channel 1, pin D1 of the package 32, may be used for traces between BGA solder balls 34 to the BGA pads 35, BGA solder balls 34 to the die 25, and the BGA pad 35 to the die 25, thereby allowing traces to run through each of devices connected to the various sides of the package 32 via the second channel 64. In this manner, the die 25 may communicate with both memory devices 54 on the top side of the package 32 and memory devices 54 that are off of the package 32 (not shown) using the traces, as discussed above. Moreover, other off-package devices on the PCB 52 may also communicate with both the die 25 and memory devices 54 via the BGA solder balls 34.

Technical effects for employing the modified and multi-functional integrated circuit package 32 architecture disclosed herein includes using multiple BGA connections on a single package (e.g., top side connecting to base die 24 and bottom side connecting to PCB 52) to allow devices that were previously disposed off of the package 32 to be located on the package 32. This modification thereby increases the PCB area 55 that may be suitable for other circuit components. For example, other components, such as power delivery components or additional application specific components, may be added to the PCB 52 without increasing PCB 52 and/or CCA size. Maintaining a compact PCB size may be especially beneficial for form-factor constrained systems, such as wireless devices that are constrained to smaller packaging for mobility. As previously mentioned, 5G application may particularly benefit from the package architecture described herein since additional components and devices may be used on unused PCB area after moving off-package devices to on-package.

The methods and devices of this disclosure may be incorporated into any suitable circuit. For example, the methods and devices may be incorporated into numerous types of devices such as microprocessors or other integrated circuits. Exemplary integrated circuits include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), application specific integrated circuits (ASICs), and microprocessors, just to name a few.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

1. An integrated circuit (IC) package, comprising:
a semiconductor die disposed on a first side of the integrated circuit (IC) package;
a first ball grid array (BGA) connection disposed on the first side of the IC package; and
a second BGA connection disposed on a second side of the IC package, wherein one or more traces are configured to route data via the first BGA connection and the second BGA connection.

2. The integrated circuit package of claim 1, wherein the first BGA connection comprises one or more ball grid array (BGA) solder balls.

3. The integrated circuit package of claim 1, where in the second BGA connection comprises one or more ball grid array (BGA) pads.

4. The integrated circuit package of claim 3, wherein the one or more BGA pads are configured to communicatively couple to at least one memory device, wherein the at least one memory device comprises static random access memory (SRAM), embedded dynamic random access memory (EDRAM), double data rate synchronous dynamic random access memory (DDR SDRAM), double data rate synchronous dynamic random access memory (DDR SDRAM), graphics double data rate synchronous dynamic random access memory (GDDR SDRAM), or a combination thereof.

5. The integrated circuit package of claim 4, wherein the semiconductor die is configured to communicate with the at least one memory device via the one or more BGA pads.

6. The integrated circuit package of claim 4, wherein the semiconductor die is configured to communicate with one or more devices disposed on a printed circuit board (PCB) via the one or more BGA solder balls, wherein the one or more BGA solder balls are connected to the PCB.

7. The integrated circuit package of claim 6, wherein the semiconductor die is configured to communicate with the one or more devices via the one or more traces and the one or more BGA solder balls.

8. A printed circuit board (PCB) assembly, comprising:
an integrated circuit (IC) package, comprising:
a semiconductor die disposed on a first side of the integrated circuit (IC) package;
a first ball grid array (BGA) connection disposed on the first side of the IC package; and
a second BGA connection disposed on a second side of the IC package, wherein one or more traces are configured to route data via the first BGA connection and the second BGA connection; and
a first memory device, wherein the semiconductor die is configured to communicate with memory device via the first BGA connection.

9. The PCB assembly of claim 8, wherein the first BGA connection comprises one or more ball grid array (BGA) solder balls.

10. The PCB assembly of claim 8, where in the second BGA connection comprises one or more ball grid array (BGA) pads.

11. The PCB assembly of claim 10, wherein the one or more BGA pads are configured to communicatively couple to the first memory device.

12. The PCB assembly of claim 11, wherein the semiconductor die is configured to communicate with the first memory device via the one or more BGA pads.

13. The PCB assembly of claim 11, wherein the semiconductor die is configured to communicate with a second memory device via the one or more BGA solder balls.

14. A field programmable gate array (FPGA) package, comprising:
one or more ball grid array (BGA) balls disposed on a first side of the FPGA package;
one or more ball grid array (BGA) pads disposed on a second side of the FPGA package; and
one or more channels configured to communicatively couple the one or more BGA balls to the one or more BGA pads.

15. The FPGA package of claim 14, wherein the first side of the FPGA package is coupled to a printed circuit board (PCB).

16. The FPGA package of claim 15, wherein the second side of the FPGA is coupled to a semiconductor die.

17. The FPGA package of claim 16, wherein the semiconductor die is configured to communicate with one or more memory devices coupled to BGA pads using the one or more channels.

18. The FPGA package of claim 16, wherein the one or more BGA balls are configured to communicatively couple to one or more devices disposed on the PCB.

19. The FPGA package of claim 18, wherein the one or more devices disposed on the PCB are configured to communicate with the semiconductor die via the one or more channels.

20. The FPGA package of claim 18, wherein the one or more devices comprise power measurement circuitry, a voltage regulator, an oscillator, or any combination thereof.
